(19) United States
(12) Patent Application Publication
(10) Pub. No.: US 2015/0048720 A1
(43) Pub. Date: Feb. 19, 2015

(54) PIEZOELECTRIC ACTUATOR MODULE AND METHOD OF MANUFACTURING THE SAME

(71) Applicant: Samsung Electro-Mechanics Co., Ltd., Suwon (KR)

(72) Inventors: Boum Seock KIM, Suwon (KR); Jung Wook SEO, Hwasung (KR)

(73) Assignee: Samsung Electro-Mechanics Co., Ltd., Suwon (KR)

(21) Appl. No.: 14/062,366

(22) Filed: Oct. 24, 2013

(30) Foreign Application Priority Data
Aug. 14, 2013 (KR) 10-2013-0096646

(51) Int. Cl. H01L 41/047

(52) U.S. Cl. CPC H01L 41/0475
USPC 310/348; 29/25.35

(57) ABSTRACT

Disclosed herein are a piezoelectric actuator module and a method of manufacturing the same. The piezoelectric actuator module includes: a plate; a piezoelectric element disposed on the plate and having a through-hole formed therein; and a feeding wire inserted into the through-hole to apply an external voltage to the piezoelectric element.

### CROSS REFERENCE(S) TO RELATED APPLICATIONS

This application claims the benefit under 35 U.S.C. Section 119 of Korean Patent Application Serial No. 10-2013-0096646, entitled “Piezoelectric Actuator Module and Method of Manufacturing the Same” filed on Aug. 14, 2013, which is hereby incorporated by reference in its entirety into this application.

### BACKGROUND OF THE INVENTION

1. Technical Field

The present invention relates to a piezoelectric actuator module, and more particularly, to a piezoelectric actuator module having a plate including a piezoelectric element disposed thereon as a basic structure, and a method of manufacturing the same.

2. Description of the Related Art

Generally, a piezoelectric actuator, which is an actuator using a piezoelectric ceramic, may be manufactured as a module attached onto a plate.

The piezoelectric actuator generates charges under mechanical pressure or tension and has a feature that it is expanded or contracted at the time of applying an electrical signal thereto. That is, the piezoelectric actuator uses a feature of the piezoelectric ceramic converting electrical energy into mechanical energy or converting the mechanical energy into the electrical energy and has been widely used in an automobile, a medical device, a camera, various other electronic devices, and the like. Recently, the demand of a fine control has increased.

A piezoelectric actuator according to the related art will be described with reference to the accompanying drawings together with Patent Document (Korean Patent Laid-Open Publication No. 10-2008-0074962).

FIG. 6 is a cross-sectional view of a piezoelectric actuator according to the related art. As shown in FIG. 6, the piezoelectric actuator according to the related art is configured to include a piezoelectric element 1 having a plurality of thin piezoelectric layers 1a disposed therein, a plurality of internal electrodes 2 inserted between the piezoelectric layers 1a, and external electrodes 3 formed on both side surfaces of the piezoelectric element 1 so as to be connected to the internal electrodes 2.

In the piezoelectric actuator according to the related art as described above, in the case in which a voltage is applied to the external electrodes 3, displacement is generated in the piezoelectric layer 1a, and a series of individual piezoelectric layers 1a are mechanically connected to each other, such that fine displacement may be obtained even at a low voltage.

As described above, the piezoelectric actuator has a structure in which the external electrodes for electrically connecting the internal electrodes to the outside are disposed on both side surfaces of the piezoelectric element. However, the external electrode having a predetermined thickness hinders a product from being miniaturized. In addition, in the case in which bonding force between the external electrode and the piezoelectric element is weak, there is a risk that an electric contact defect will be generated between the external electrode and the internal electrode.

As another structure for electrical connection with the internal electrode, a structure supplying an external voltage through a feeding wire has been suggested. That is, in this scheme, an electrode wire connecting the internal electrodes having the respective polarities integrally with each other is exposed to a surface of the piezoelectric element and the feeding wire is connected to the surface of the piezoelectric element by soldering to apply the external voltage through the feeding wire.

However, since the soldering should be directly performed on the surface of the piezoelectric element, local depoling is generated in the piezoelectric element due to a high surface temperature (approximately 350° C.) of the piezoelectric element caused by the soldering. As a result, piezoelectric characteristics are deteriorated.

### RELATED ART DOCUMENT

### Patent Document

(Patent Document 1) Korean Patent Laid-Open Publication No. 10-2008-0074962

### SUMMARY OF THE INVENTION

An object of the present invention is to provide a piezoelectric actuator module capable of preventing deterioration of characteristics of a piezoelectric element due to soldering, being advantageous for miniaturization of a product, and securing connection reliability by suggesting a connecting structure in a new scheme, and a method of manufacturing the same.

According to an exemplary embodiment of the present invention, there is provided a piezoelectric actuator module including: a plate; a piezoelectric element disposed on the plate and having a through-hole formed therein; and a feeding wire inserted into the through-hole to apply an external voltage to the piezoelectric element.

One end of the feeding wire inserted into the through-hole may be fixed to a surface of the plate by soldering.

The piezoelectric actuator module may further include a conductive resin filled in the through-hole.

The piezoelectric element may include a plurality of piezoelectric layers stacked in a thickness direction and first and second electrode plates alternately stacked, having the piezoelectric layer therebetween.

The through-hole may include a first through-hole penetrating through the first electrode plate and a second through-hole penetrating through the second electrode plate.

The feeding wire may include a first feeding wire inserted into the first through-hole to thereby be connected to the first electrode plate and a second feeding wire inserted into the second through-hole to thereby be connected to the second electrode plate.

The piezoelectric actuator module may further include an insulating layer disposed between the plate and the piezoelectric element.

According to another exemplary embodiment of the present invention, there is provided a method of manufacturing a piezoelectric actuator module, including: soldering one end of a feeding wire to an upper surface of a plate; and bonding a piezoelectric element in which a through-hole is formed onto the upper surface of the plate and penetrating the feeding wire through the through-hole.

The method may further include interposing an insulating layer between the plate and the piezoelectric element at the time of bonding the piezoelectric element onto the upper surface of the plate.

The method may further include, after the penetrating of the feeding wire through the through-hole, filling an inner portion of the through-hole with a conductive resin.

### BRIEF DESCRIPTION OF THE DRAWINGS

FIG. 1 is a perspective view showing an appearance of a piezoelectric actuator module according to an exemplary embodiment of the present invention;

FIG. 2 is a cross-sectional view taken along the line I-I′ of FIG. 1; and

FIGS. 3 to 5 are views sequentially showing processes of a method of manufacturing a piezoelectric actuator module according to the exemplary embodiment of the present invention.

FIG. 6 is a cross-sectional view of a piezoelectric actuator according to the related art.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art.

Terms used in the present specification are for explaining exemplary embodiments rather than limiting the present invention. Unless explicitly described to the contrary, a singular form includes a plural form in the present specification. In addition, components, steps, operations, and/or elements mentioned in the present specification do not exclude the existence or addition of one or more other components, steps, operations, and/or elements.

Hereinafter, a configuration and an acting effect of exemplary embodiments of the present invention will be described in more detail with reference to the accompanying drawings.

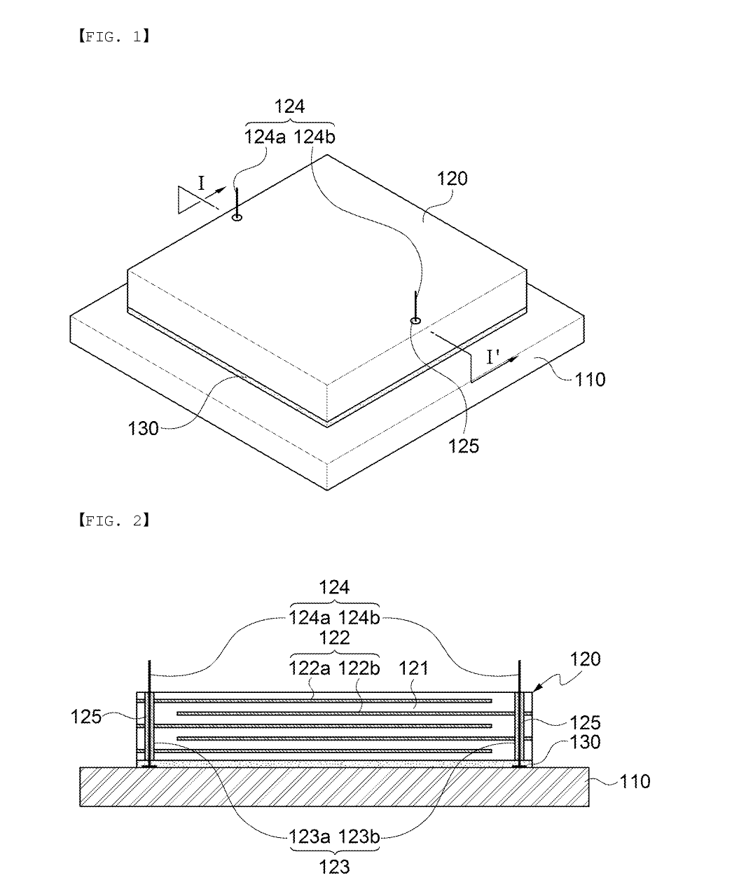

FIG. 1 is a perspective view showing an appearance of a piezoelectric actuator module according to an exemplary embodiment of the present invention; and FIG. 2 is a cross-sectional view taken along the line I-I′ of FIG. 1. Additionally, components shown in the accompanying drawings are not necessarily shown to scale. For example, sizes of some components shown in the accompanying drawings may be exaggerated as compared with other components in order to assist in the understanding of the exemplary embodiments of the present invention. Meanwhile, throughout the accompanying drawings, the same reference numerals will be used to describe the same components. For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure.

Referring to FIGS. 1 and 2, the piezoelectric actuator module 100 according to the exemplary embodiment of the present invention has a plate 110 having a piezoelectric element 120 disposed thereon as a basic structure.

The piezoelectric element 120 is a bimorph type piezoelectric substance in which a plurality of piezoelectric layers 121 typically made of lead zirconium titanite ceramics (PZT) are stacked in a thickness direction, wherein the respective piezoelectric layers 121 may have first and second electrode plates 122a and 122b alternately inserted and stacked therebetween. That is, one piezoelectric layer 121, the first electrode plate 122a, another piezoelectric layer 121, and the second electrode plate 122b are alternately stacked, thereby making it possible to manufacture the piezoelectric element 120.

Here, a positive (+) voltage is applied to the first electrode plate 122a and a negative (−) voltage is applied to the second electrode plate 122b (or a negative (−) voltage is applied to the first electrode plate 122a and a positive (+) voltage is applied to the second electrode plate 122b. Therefore, deformation such as extension/contraction may be generated in the piezoelectric element in response to an electric field in a forward direction that is the same as that a polarization direction of each piezoelectric layer 121 or an electric field in a reverse direction opposite to the polarization direction.

In addition, the plate 110 functions as a displacement amplifying mechanism for amplifying the deformation of the piezoelectric element 120 as described above and also functions as a support firmly supporting the piezoelectric element 120 so as not to be easily broken. Therefore, it is preferable that the plate 110 has an appropriate elastic modulus in consideration of the amplification of the vibration displacement and is made of a metal material having flexibility so as to be flexibly bent by the deformation of the piezoelectric element 120.

The plate 110 may be formed in an approximately flat plate shape, and the plate 110 and the piezoelectric element 120 may have an insulating layer 130 disposed therebetween for adhesion and insulation of the piezoelectric element 120. Here, it is preferable that the insulating layer 130 is formed at a thin film thickness. The reason is that the insulating layer 130 absorbs vibration energy to decrease amplitude of the plate 110 in the case in which the insulating layer 130 is excessively thick.

The piezoelectric element 120 includes a through-hole 123 penetrating therethrough in a thickness direction and a feeding wire 124 made of at least any one metal selected from a group consisting of Ni, Al, Fe, Cu, Ti, Cr, Au, Ag, and Pd having excellent conductivity is inserted into he through-hole 123, such that an external voltage may be supplied to the first and second electrode plates 122a and 122b.

More specifically, the through-hole 123 may include first and second through-holes 123a and 123b, wherein the first through-hole 123a may penetrate through the first electrode plate 122a and the second through-hole 123b may penetrate through the second electrode plate 122b.

That is, the first electrode plate 122a may be formed to be biased toward one side thereof in a length direction of the piezoelectric element 120 and be penetrated by the first through-hole 123a formed at one side thereof. To the contrary, the second electrode plate 122b may be formed to be biased toward the other side of the first electrode plate 122a and be penetrated by the second through-hole 123b formed at the other side of the first electrode plate 122a.

In addition, the feeding wire 124 may include a first feeding wire 124a inserted into the first through-hole 123a and a second feeding wire 124b inserted into the second through-hole 123b, corresponding to the first through-hole 123a and he second through-hole 123b. Therefore, the first feeding wire 124a may apply a positive (+) voltage (or a negative (−) voltage) to the first electrode plate 122a while forming an electrical contact with the first electrode plate 122a, and the second feeding wire 124b may apply a negative (−) voltage (or a positive (+) voltage) to the second electrode plate 122b while forming an electrical contact with the second electrode plate 122b.

As described above, the feeding wire 124 may be inserted into the through-hole 123 of the piezoelectric element 120 to thereby be electrically connected to the electrode plate 122. However, since the feeding wire 124 has a very fine diameter, it may be substantially difficult to form the through-hole 123 having a diameter corresponding to that of the feeding wire 124, such that an electrical contact defect between the feeding wire 124 and the electrode plate 122 may be generated. Therefore, the piezoelectric actuator module 100 according to the exemplary embodiment of the present invention may further include a conductive resin 125, for example, a conductive epoxy resin, filled in the through-hole 123 in order to increase reliability of the contact between the feeding wire 124 and the electrode plate 122.

Meanwhile, one end of the feeding wire 124 inserted into the through-hole 123 may be fixed to a surface of the plate 110. The feeding wire 124 may be fixed by performing soldering using a solder paste. Therefore, coupling force between the feeding wire 124 and the plate 110 is increased, thereby making it possible to prevent the feeding wire 124 from being easily separated from the piezoelectric element 120.

With the structure of the piezoelectric actuator module according to the exemplary embodiment of the present invention as described above, a unit (that is, an external electrode in an actuator according to the related art) for electrically connecting the electrode plate in the piezoelectric element to the outside needs not to be separately provided at any outer side portion of the piezoelectric element, which is advantageous for miniaturization of a product.

In addition, since soldering is not directly performed on the piezoelectric element 120 unlike the related art, performance deterioration such as a depoling phenomenon of the piezoelectric element due to thermal stress generated at the time of performing the soldering may be prevented. A detailed description thereof will be provided below in a description of a method of manufacturing a piezoelectric actuator module according to the exemplary embodiment of the present invention.

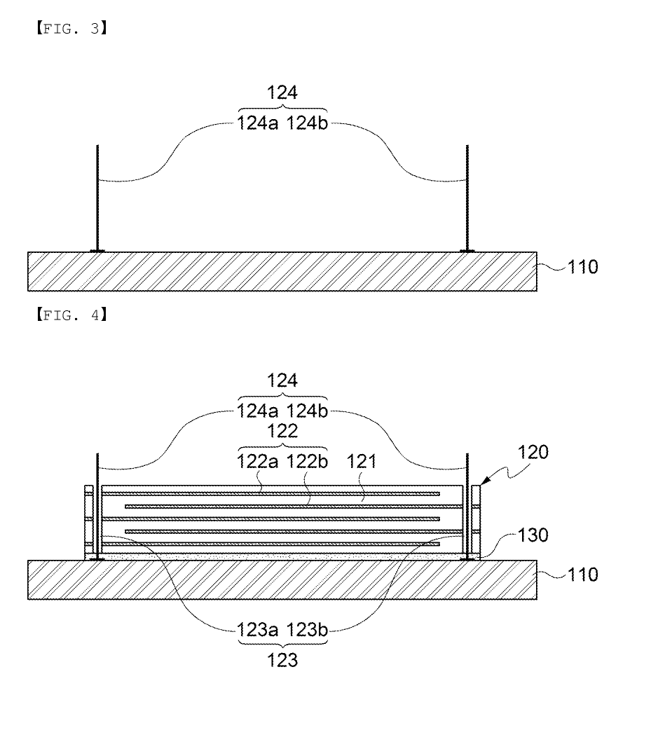

FIGS. 3 to 5 are views sequentially showing processes of a method of manufacturing a piezoelectric actuator module according to the exemplary embodiment of the present invention. First, as shown in FIG. 3, an operation of soldering one end of the feeding wire 124 to an upper surface of the plate 110 is performed.

The feeding wire 124 includes two feeding wires, that is, first and second feeding wires 124a and 124b for positive (+) and negative (−) voltages. As described above, in the case in which the soldering is performed on the surface of the plate 110 made of a metal material rather than a surface of the piezoelectric element 120, coupling force may be increased and the performance deterioration of the piezoelectric element 120 may be prevented as described above.

Then, as shown in FIG. 4, an operation of bonding the piezoelectric element 120 in which the through-hole 123 is formed onto the plate 100 is performed.

In this case, it is preferable that the piezoelectric element 120 is bonded in a state in which the insulating layer 130 is interposed between the plate 110 and the piezoelectric element 120 in order to improve adhesion between the plate 110 and the piezoelectric element 120 and insulate between the plate 110 and the piezoelectric element 120. The insulating layer 130 may be formed by coating the surface of the plate 110 with an insulating resin by a method such as a spin coating method, or the like, or be formed by performing oxidation such as anodizing, or the like, on the surface of the plate surface 110 made of a metal material.

The through-hole 123 may be formed at a predetermined position of the piezoelectric element 120 using a mechanical drill or a laser drill before the bonding of the piezoelectric element 120. In this case, the first through-hole 123a penetrating through the first electrode plate 122a and the second through-hole 123b penetrating through the second electrode plate 122b are drilled.

In addition, at the time of bonding the piezoelectric element 120, the feeding wire 124 penetrates through and is bonded to the through-hole 123, as shown in FIG. 4. In this case, the first feeding wire 124a penetrates through the first through-hole 123a, and the second feeding wire 124b penetrates through the second through-hole 123b.

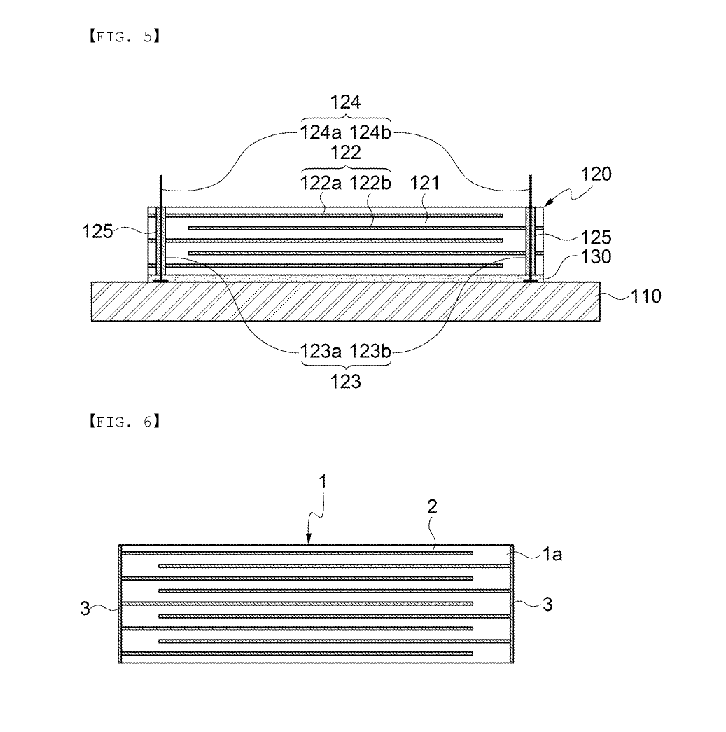

After the piezoelectric element 120 is bonded onto the plate 110 as described above, finally, an operation of filling an inner portion of the through-hole 123 with a conductive resin 125 for increasing reliability of a contact between the feeding wire 124 and the electrode plate 122 is performed as shown in FIG. 5, thereby making it possible to complete the piezoelectric actuator module according to the exemplary embodiment of the present invention.

As described above, in the method of manufacturing a piezoelectric actuator module according to the exemplary embodiment of the present invention, the soldering is performed in advance on the plate 110 rather than the piezoelectric element 120 to form the feeding wire 124, the performance deterioration of the piezoelectric element 120 may be prevented unlike the related art and reliability of connection may be increased due to more safe solder.

According to the exemplary embodiment of the present invention, the external electrode according to the related art used in order to electrically connect the electrode plate in the piezoelectric element to the outside and having a predetermined thickness needs not to be separately provided at an outer side of the piezoelectric element, which is advantageous for miniaturization of a product.

In addition, since soldering is not directly performed on the piezoelectric element unlike the related art, performance deterioration such as a depoling phenomenon of the piezoelectric element due to thermal stress generated at the time of performing the soldering may be prevented.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A piezoelectric actuator module comprising:
a plate;
a piezoelectric element disposed on the plate and having a through-hole formed therein; and
a feeding wire inserted into the through-hole to apply an external voltage to the piezoelectric element.

2. The piezoelectric actuator module according to claim 1, wherein one end of the feeding wire inserted into the through-hole is fixed to a surface of the plate by soldering.

3. The piezoelectric actuator module according to claim 1, further comprising a conductive resin filled in the through-hole.

4. The piezoelectric actuator module according to claim 1, wherein the piezoelectric element includes a plurality of piezoelectric layers stacked in a thickness direction and first and second electrode plates alternately stacked, having the piezoelectric layer therebetween.

5. The piezoelectric actuator module according to claim 4, wherein the through-hole includes a first through-hole penetrating through the first electrode plate and a second through-hole penetrating through the second electrode plate.

6. The piezoelectric actuator module according to claim 5, wherein the feeding wire includes a first feeding wire inserted into the first through-hole to thereby be connected to the first electrode plate and a second feeding wire inserted into the second through-hole to thereby be connected to the second electrode plate.

7. The piezoelectric actuator module according to claim 1, further comprising an insulating layer disposed between the plate and the piezoelectric element.

8. A method of manufacturing a piezoelectric actuator module, comprising:
soldering one end of a feeding wire to an upper surface of a plate; and
bonding a piezoelectric element in which a through-hole is formed onto the upper surface of the plate and penetrating the feeding wire through the through-hole.

9. The method according to claim 8, further comprising interposing an insulating layer between the plate and the piezoelectric element at the time of bonding the piezoelectric element onto the upper surface of the plate.

10. The method according to claim 8, further comprising, after the penetrating of the feeding wire through the through-hole, filling an inner portion of the through-hole with a conductive resin.
